(19) United States
(12) Patent Application Publication
(10) Pub. No.: US 2025/0179644 A1
(43) Pub. Date: Jun. 5, 2025

(54) RADIATION SHIELD AND SUBSTRATE PROCESSING APPARATUS INCLUDING THE SAME

(71) Applicant: SAMSUNG ELECTRONICS CO., LTD., SUWON-SI (KR)

(72) Inventors: Yongkeun Kang, Suwon-si (KR); Sunguk Kim, Suwon-si (KR); Jeonghoon Shin, Suwon-si (KR); Daegyu Lim, Suwon-si (KR); Jinwoong Cho, Suwon-si (KR); Taepyo Hong, Suwon-si (KR); Hosang Ryu, Suwon-si (KR); Sanghyun Byun, Suwon-si (KR); Semin Lee, Suwon-si (KR); Sangchul Han, Suwon-si (KR)

(21) Appl. No.: 18/953,943

(22) Filed: Nov. 20, 2024

(30) Foreign Application Priority Data
Dec. 4, 2023 (KR) 10-2023-0173444

(51) Int. Cl. C23C 16/52; C23C 16/458

(52) U.S. Cl. CPC C23C 16/52; C23C 16/458

(57) ABSTRACT

A radiation shield includes a shield plate that includes a first portion, a second portion, and a plurality of pin holes that pass through the shield plate. The first portion includes a plurality of through holes that pass through the shield plate, and the second portion does not include the plurality of through holes.

### CROSS-REFERENCE TO RELATED APPLICATION

This application claims priority under 35 U.S.C. § 119 from Korean Patent Application No. 10-2023-0173444, filed on Dec. 4, 2023 in the Korean Intellectual Property Office, the contents of which are herein incorporated by reference in their entirety.

### TECHNICAL FIELD

Embodiments of the inventive concept are directed to a radiation shield and a substrate processing apparatus that includes the same, and more particularly, to a radiation shield that has an asymmetric shape and a substrate processing apparatus that includes the same.

### DISCUSSION OF THE RELATED ART

Integrated circuits include a considerable number of semiconductor devices. Semiconductor devices are manufactured by various processes, and the various processes include a deposition process. A deposition process includes a chemical vapor deposition (CVD) process. The non-uniformity of physical properties of deposited materials and the non-uniformity of the thickness of a layer may adversely affect the performance of an integrated circuit.

Substrate processing apparatuses used in a deposition process may need to heat a chuck plate. Because the chuck plate needs to maintain a high temperature, a radiation shield may be disposed adjacent to the chuck plate so that the high temperature of the chuck plate is more easily maintained.

### SUMMARY

Embodiments of the inventive concept provides a radiation shield that includes a plurality of through holes asymmetrically arranged and a substrate processing apparatus that includes the radiation shield, which increases the productivity and quality of substrates.

A radiation shield according to an embodiment includes a shield plate that includes a first portion, a second portion, and a plurality of pin holes that pass through the shield plate. The first portion includes a plurality of through holes that pass through the shield plate, and the second portion does not include the plurality of through holes.

A substrate processing apparatus according to an embodiment includes a housing that provides a chamber, a chuck plate disposed in the chamber, a shaft disposed at a lower end of the chuck plate and that supports the chuck plate, a radiation shield disposed under and spaced apart from the chuck plate, wherein the shaft passes through the radiation shield, and a substrate entrance formed in one surface of the housing and located a first direction from the chuck plate. The radiation shield includes a shield plate that includes a first portion, a second portion, and a plurality of pin holes that pass through the shield plate. The first portion includes a plurality of through holes that pass through the shield plate and the second portion does not include the plurality of through holes.

A radiation shield according to an embodiment includes a shield plate that includes a first portion, a second portion, and a plurality of pin holes that pass through the shield plate, and the shield plate has a planar circular shape. The first portion and the second portion are divided by a center line that passes through a center of the shield plate. The shield plate includes a plurality of through holes that pass through the shield plate. The plurality of through holes are disposed in first portion and along the center line of the shield plate, and the second portion does not include the plurality of through holes. A first virtual circle, a second virtual circle, a third virtual circle, and a fourth virtual circle, which are concentric circles of the shield plate, are defined on the shield plate. A first radius is a radius of the first virtual circle from the center, a second radius is a radius of the second virtual circle from the center, a third radius is a radius of the third virtual circle from the center, a fourth radius is a radius of the fourth virtual circle from the center, and lengths of the first to fourth radii increase in an order of the first radius, the second radius, the fourth radius, and the third radius and a difference between the second radius and the third radius is greater than a difference between the first radius and the second radius. The plurality of through holes include first through holes formed along the first virtual circle, second through holes formed along the second virtual circle, and third through holes formed along the third virtual circle. Separation distances between the first through holes are equal to each other, separation distances between the second through holes are equal to each other, separation distances between the third through holes are equal to each other, and a number of through holes increases in an order of the first through holes, the second through holes, and the third through holes. The plurality of pin holes are uniformly formed along the fourth virtual circle. A first diameter is a diameter of each of the plurality of through holes, a second diameter is a diameter of each of the plurality of pin holes, and the second diameter is greater than the first diameter. The first diameter is between about 10 mm and about 16 mm, the second diameter is between about 15 mm and about 20 mm, a separation distance between the plurality of through holes is between about 16 mm and about 24 mm, and a thickness of the shield plate is between about 2 mm and about 4 mm.

### BRIEF DESCRIPTION OF THE DRAWINGS

FIG. 1 is a plan view of a radiation shield according to an embodiment.

FIG. 2A is a cross-sectional view of a substrate processing apparatus that includes a radiation shield, according to an embodiment.

FIG. 2B is a cross-sectional view of a substrate processing apparatus that includes a radiation shield, according to an embodiment.

FIG. 3 illustrates extinction coefficient values of a substrate when no radiation shield is provided, and when a radiation shield according to an embodiment is provided.

FIG. 4 illustrates a radiation shield according to an embodiment.

### DETAILED DESCRIPTION

Hereinafter, embodiments will be described in detail with reference to the accompanying drawings.

Embodiments may be provided so that this disclosure will be thorough and complete and will fully convey the scope of the inventive concept to those of ordinary skill in the art. The following embodiments may be modified into various forms, and the inventive concept is not limited to the following embodiments.

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

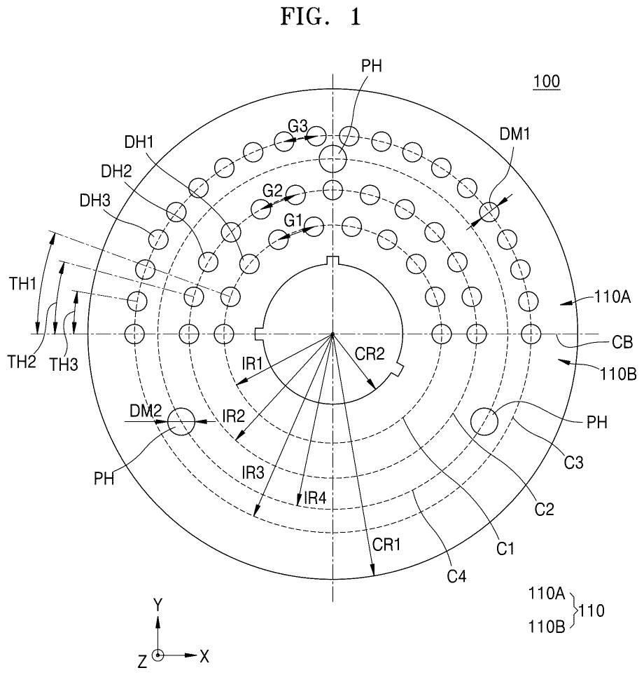

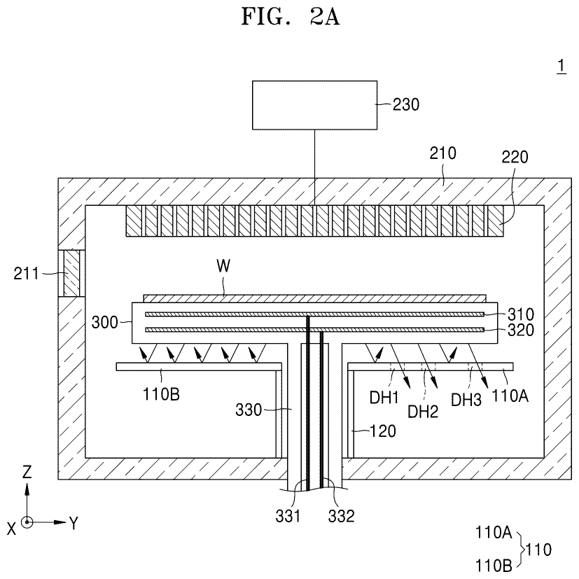

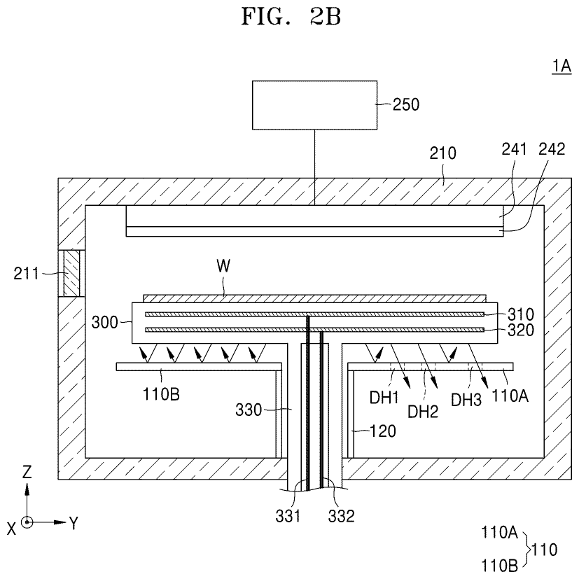

FIG. 1 is a plan view of a radiation shield 100 according to an embodiment. FIG. 2A is a cross-sectional view of a substrate processing apparatus 1 that includes a radiation shield 100, according to an embodiment. FIG. 2B is a cross-sectional view of a substrate processing apparatus 1A that includes a radiation shield 100, according to an embodiment.

Herein, a first direction may denote an X direction, a second direction may denote a Y direction, and the first direction and the second direction may be perpendicular to each other. A third direction may denote a Z direction, and the third direction may be perpendicular to each of the first direction and the second direction. A horizontal plane may be referred to as an X-Y plane. An upper surface of a certain target may denote one surface disposed in a positive third direction with respect to the certain target, and a lower surface of a certain target may denote one surface disposed in a negative third direction with respect to the certain target.

Referring to FIGS. 1 and 2A, the substrate processing apparatus 1 according to an embodiment includes a housing 210, a chuck plate 300 provided in a chamber of the housing 210 and configured so that a substrate W can be disposed on an upper surface of the chuck plate 300, an electrode member 310 provided in the chuck plate 300, a heater 320, a shaft 330 that supports the chuck plate 300 at a lower surface of the chuck plate 300, a radiation shield 100 that faces the lower surface of the chuck plate 300 at a lower portion of the chuck plate 300, a shield supporter 120 that supports the radiation shield 100, a first line 331 that transmits a current to the electrode member 310, a second line 332 that transmits power or heat to the heater 320, a substrate entrance 211 that is spaced apart from one side of the chuck plate 300 and is formed on a side surface of the housing 210, an injection device 220 provided on the chuck plate 300, and a gas supply unit 230.

The substrate processing apparatus 1 according to an embodiment includes chemical vapor deposition (CVD) equipment. In addition, the substrate processing apparatus 1 according to an embodiment includes physical vapor deposition (PVD) equipment. This will be described below with reference to FIG. 2B.

The chamber is an internal space of the housing 210 that provides a space that is independent of the outside. For example, the chamber supports a vacuum pressure of about 1×10⁻⁸ Torr to about 1×10⁻⁴ Torr. The housing 210 includes the substrate entrance 211 through which the substrate W is loaded into or unloaded from the housing 210. For example, the substrate entrance 211 can be opened or closed through a slit valve. The slit valve opens the substrate entrance 211 when the substrate W is transferred by an external robot arm, and when performing a substrate processing process, the slit valve closes the substrate entrance 211.

The chuck plate 300 is disposed in the chamber, which is the internal space of the housing 210. The chuck plate 300 is disposed on the shaft 330, which passes through the housing 210. The shaft 330 can rotate the chuck plate 300. The substrate W is disposed on an upper surface of the chuck plate 300. The chuck plate 300 includes the heater 320. The heater 310 is supplied with power or heat to heat the chuck plate 300 and heats the substrate W with heat from the chuck plate 300. For example, the heater 310 can heat the substrate W to a high temperature of about 300° C. or more.

The injection device 220 is disposed at an upper portion of the chamber. The gas supply unit 230 supplies a reactant gas to the injection device 220. The injection device 220 injects the reactant gas onto the substrate W. The reactant gas forms a thin film on the substrate W.

The radiation shield 100 includes a shield plate 110, and a plurality of through holes DH1 to DH3 pass through the shield plate 110 and are asymmetrically arranged on the shield plate 110. A plurality of through holes DH1 to DH3 are formed in a first portion 110A of the shield plate 110, but no through holes DH1 to DH3 are formed in a second portion 110B of the shield plate 110. The shield plate 110 includes a material that has a low thermal conductance and a low reactivity with a chemical material. For example, the shield plate 110 includes a material that includes aluminum oxide (Al₂O₃).

The first portion 110A and the second portion 110B of the shield plate 110 are divided from each other by a virtual center line CB that passes through the center of the shield plate 110. In an embodiment, the shield plate 110 has a circular planar shape. However, embodiments are not necessarily limited thereto. A vertical-direction thickness of the shield plate 110 is between about 2 mm and about 4 mm.

An external diameter CR1 of the shield plate 110 is between about 130 mm and about 170 mm. For example, the external diameter CR1 of the shield plate 110 has a range similar to the radius of the chuck plate 300. As shown in FIG. 2A, the shaft 330 passes through the center of the shield plate 110, and thus, an internal hole that includes the center of the shield plate 110 is formed. The radius of the internal hole of the shield plate 110, which is an internal diameter CR2 of the shield plate 110, is between about 35 mm and about 55 mm. The internal diameter CR2 of the shield plate 110 is determined based on the radius of the shaft 330 that passes through the shield plate 110, and thus, embodiments of the inventive concept are not necessarily limited to a numerical value of the internal diameter CR2 of the shield plate 110.

The plurality of through holes DH1 to DH3 are formed in the first portion 110A divided with respect to the center line CB, which is a boundary. In addition, the plurality of through holes DH1 to DH3 are formed in the center line CB. The plurality of through holes DH1 to DH3 include first through holes DH1, second through holes DH2, and third through holes DH3. Diameters of the plurality of through holes DH1 to DH3 may differ from each other, or may be equal to each other.

For example, as shown in FIG. 1, diameters of the first through holes DH1, diameters of the second through holes DH2, and diameters of the third through holes DH3 are equal to each other, and a first diameter DM1, which is the diameter of each of the first through holes DH1, the second through holes DH2, and the third through holes DH3, is between about 10 mm and about 16 mm, or may be about 13 mm.

A first virtual circle C1, a second virtual circle C2, and a third virtual circle C3, which are concentric circles within the shield plate 110, may be defined. A first radius IR1, which is a radius of the first virtual circle C1 from the center of the shield plate 110, is less than a second radius IR2, which is a radius of the second virtual circle C2 from the center of the shield plate 110. The second radius IR2 is less than a third radius IR3 which is a radius of the third virtual circle C3 from the center of the shield plate 110. For example, a value of the first radius IR1, a value of the second radius IR2, and a value of the third radius IR3 increase in the order of the first radius IR1, the second radius IR2, and the third radius IR3. In an embodiment, the first radius IR1 is between about 65 mm and about 85 mm, the second radius IR2 is between about 90 mm and about 115 mm, and the third radius IR3 is between about 120 mm and about 150 mm. However, embodiments of the inventive concept are not necessarily limited to the aforementioned values of the first radius IR1, the second radius IR2, and the third radius IR3.

In an embodiment, a difference between the first radius IR1 and the second radius IR2 differs from a difference between the second radius IR2 and the third radius IR3. As shown in FIG. 1, the difference between the first radius IR1 and the second radius IR2 is less than the difference between the second radius IR2 and the third radius IR3. This may be because an inner side of the chuck plate 300 has a higher temperature than an outer side of the chuck plate 300, and the second through holes DH2 are disposed closer to the center of the shield plate 110 to offset a temperature difference.

As shown in FIG. 1, the first through holes DH1 are formed along the first virtual circle C1 in the first portion 110A and the center line CB of the shield plate 110. In addition, two of the first through holes DH1 are disposed at a location where the first virtual circle C1 intersects with the center line CB. For example, eight to twelve first through holes DH1 are formed along the first virtual circle C1. For example, as shown in FIG. 1, ten first through holes DH1 are formed along the first virtual circle C1.

The second through holes DH2 are formed along the second virtual circle C2 in the first portion 110A and the center line CB of the shield plate 110. In addition, two of the second through holes DH2 are disposed at a location where the second virtual circle C2 intersects with the center line CB. For example, twelve to sixteen second through holes DH2 are formed along the second virtual circle C2. For example, as shown in FIG. 1, thirteen second through holes DH2 are formed along the second virtual circle C2.

The third through holes DH3 are formed along the third virtual circle C3 in the first portion 110A and the center line CB of the shield plate 110. In addition, two of the third through holes DH3 are disposed at a location where the third virtual circle C3 intersects with the center line CB. For example, sixteen to twenty-four third through holes DH3 are formed along the third virtual circle C3. For example, as shown in FIG. 1, twenty third through holes DH3 are formed along the third virtual circle C3.

A fourth virtual circle C4, which is a concentric circle in the shield plate 110, may be defined. For example, the first virtual circle C1, the second virtual circle C2, the third virtual circle C3, and the fourth virtual circle C4 are all concentric. A plurality of pin holes PH are formed along the fourth virtual circle C4. The plurality of pin holes PH are formed in the shield plate 110 so that a plurality of pins that can raise or lower the substrate W can pass through the shield plate 110. For clarity of illustration, the plurality of pins are omitted from FIGS. 2A and 2B.

For example, as shown in FIG. 1, the plurality of pin holes, such as the three pin holes PH that pass through the shield plate 110, are formed, but are not necessarily limited thereto. The plurality of pin holes PH allow pins that raise or lower the substrate W to pass through the radiation shield 100B. The plurality of pin holes PH are uniformly distributed along the fourth virtual circle C4. A second diameter DM2 of each of the plurality of pin holes PH is between about 15 mm and about 21 mm, or may be about 18 mm.

A fourth radius IR4 of the fourth virtual circle C4 from the center of the shield plate 110, is less than the third radius IR3 and greater than the first radius IR1 and the second radius IR2. For example, the fourth radius IR4 is between about 110 mm and about 130 mm. The fourth radius IR4 can be determined based on positions of the plurality of pin holes PH, and thus, embodiments of the inventive concept are not necessarily limited to a numerical value of the fourth radius IR4.

The first through holes DH1 are spaced apart from each other by a first interval G1. Likewise, the second through holes DH2 are spaced apart from each other by a second interval G2. Similarly, the third through holes DH3 are spaced apart from each other by a third interval G3.

The first through holes DH1 are spaced apart from each other by uniform intervals along the first virtual circle C1. The second through holes DH2 are spaced apart from each other by uniform intervals along the second virtual circle C2. The third through holes DH3 are spaced apart from each other by uniform intervals along the first virtual circle C1. For example, the first interval G1, the second interval G2, and the third interval G3 are substantially uniform. For example, each of the first interval G1, the second interval G2, and the third interval G3 is between about 20 mm and about 30 mm.

Furthermore, the first interval G1, the second interval G2, and the third interval G3 may be changed based on the diameter of each of the first through holes DH1, the second through holes DH2, and the third through holes DH3, the length of each of the first radius IR1, the second radius IR2, and the third radius IR3, and the number of through holes disposed in each of the first virtual circle C1, the second virtual circle C2, and the third virtual circle C3.

As described above, when the first interval G1, the second interval G2, and the third interval G3 are substantially uniform, a first angle TH1, which is an angle interval with respect to the center of the shield plate 110 that separates adjacent first through holes DH1, is greater than a second angle TH2, which is an angle interval with respect to the center of the shield plate 110 that separates adjacent second through holes DH2. Likewise, the second angle TH2 is greater than a third angle TH3, which is an angle interval with respect to the center of the shield plate 110 that separates adjacent third through holes DH3. For example, the first angle TH1 is between about 15 degrees to about 25 degrees. The second angle TH2 is between about 12 degrees and about 18 degrees. The third angle TH3 is between about 8 degrees and about 12 degrees. For example, the number of through holes disposed farther away from the center of the shield plate 110 increases, and thus, an angle that separates adjacent through holes decreases. As shown in FIG. 1, the total number of first through holes DH1 along the first virtual circle C1 is ten and the total number of third through holes DH3 along the third virtual circle C3 is twenty, and thus, the first angle TH1 is greater than the third angle TH3. A relationship between the first angle TH1 and the second angle TH2 and a relationship between the second angle TH2 and the third angle TH3 is similar to a relationship between the first angle TH1 and the third angle TH3.

A ratio of an area of a planar surface of the first portion 110A to an area of a planar surface of the second portion 110B is about 0.7 to about 0.9. For example, due to the asymmetric arrangement of the plurality of through holes DH1 to DH3, an area of the first portion 110A is less than that of the second portion 110B.

The housing 210 includes the substrate entrance 211 through which the substrate W can be loaded into or unloaded from the housing 210. The substrate entrance 211 is formed in a sidewall of the housing 210. For example, as shown in FIG. 2A, the substrate entrance 211 is formed in a sidewall of the housing 210 in a negative second direction from the chuck plate 300.

Due to an asymmetry of the shape of the housing 210 that results from the substrate entrance 211, a temperature gradient of the chuck plate 300 can occur. For example, because the substrate entrance 211 is disposed at the sidewall of the housing 210 in the negative second direction from the chuck plate 300, the housing does not have a symmetric shape. In addition, the substrate entrance 211 may be less insulated than the housing 210.

The chuck plate 300 is heated by the heater 320 to a high temperature of about 300° C. or more. In radiation-based heat transfer, it is known that the amount of heat transfer based on radiation is proportional to four times the absolute temperature value of the object. For example, when performing a deposition process when the temperature of the chuck plate 300 is high, a temperature gradient of the chuck plate 300 is not uniform due to the asymmetry of the shape of the housing 210 and that the substrate entrance 211 is disposed at the sidewall of the housing 210.

When the temperature gradient of the chuck plate 300 is not uniform, the physical properties and thickness of a thin film formed on the substrate W through deposition might not be uniform on the chuck plate 300. For example, when the temperature gradient of the chuck plate 300 occurs, the thickness of a thin film formed through deposition can vary, or the physical properties of the thin film, such as the roughness of a surface layer of the thin film and the difference in density of the thin film, can change. Therefore, when the temperature gradient of the chuck plate 300 occurs, productivity of a substrate processing process of depositing the substrate W may decrease, and the quality of the substrate W may be reduced.

In the substrate processing apparatus 1 that includes the radiation shield 100 according to an embodiment, the radiation shield 100 is disposed under the chuck plate 300. Accordingly, the amount of heat radiation that occurs in the chuck plate 300 and is transferred to a side surface and a lower surface of the housing 210 decreases through the radiation shield 100, thereby more easily heating the chuck plate 300 and maintaining the temperature of the chuck plate 300.

However, due to the asymmetry of shape of the housing 210 and the insulation differences between the substrate entrance 211 and the housing 210 described above, the temperature gradient of the chuck plate 300 is not uniform. For example, a temperature of the chuck plate 300 near where the substrate entrance 211 is disposed is lower than that of the chuck plate 300 at an opposite portion.

Based on the asymmetric arrangement of the plurality of through holes DH1 to DH3, the radiation shield 100 can improve the temperature gradient of the chuck plate 300. For example, the radiation shield 100 is disposed so that the second portion 110B of the radiation shield 100 is disposed closer to the substrate entrance 211 and the first portion 110A of the radiation shield 100 is disposed farther from the substrate entrance 211.

The asymmetric temperature gradient of the chuck plate 300 may be corrected by the asymmetric radiation shield 100. Therefore, by using the radiation shield 100 and the substrate processing apparatus 1 that includes the same according to an embodiment, the temperature gradient of the chuck plate 300 becomes more uniform. In addition, because the temperature gradient of the chuck plate 300 is more uniform, the quality of the substrate W, on which a substrate processing process has been performed, is enhanced. For example, the substrate processing apparatus 1 according to an embodiment increases the productivity and quality of the substrate W.

The first portion 110A and the second portion 110B of the radiation shield 100 are disposed based on the insulation and the asymmetry of shape of the housing 210. As described above, the first portion 110A is disposed farther away from the substrate entrance 211, and the second portion 110B is disposed closer to the substrate entrance 211. For example, the center line CB of the shield plate 110 described above is perpendicular to a first reference direction, which is a direction toward the substrate entrance 211 from the center of the shield plate 110, and the radiation shield 100 is disposed so that the first portion 110A is disposed farther away from the substrate entrance 211.

For example, as shown in FIG. 2A, the first portion 110A that includes the first through holes DH1, the second through holes DH2, and the third through holes DH3 is disposed farther away from the substrate entrance 211. An arrow under the chuck plate 300 shows that heat radiation emitted from the heated chuck plate 300 does not pass through the second portion 110B of the radiation shield 100 and is reflected from the second portion 110B. In addition, the arrow shows that a portion of the heat radiation emitted from the heated chuck plate 300 passes through the plurality of through holes DH1 to DH3 at the first portion 110A of the radiation shield 100.

Referring to FIG. 2B, in an embodiment, a substrate processing apparatus 1A includes a plasma electrode 241, a target 242, and a high frequency power supply unit 250. For example, the substrate processing apparatus 1A of FIG. 2B includes PVD equipment.

The plasma electrode 241 and the target 242 are disposed at the upper portion of a housing 210 and face a substrate W disposed on a chuck plate 300. The plasma electrode 241 is connected to the high frequency power supply unit 250, which supplies high frequency power. The plasma electrode 241 is supplied with the high frequency power and generates plasma in the chamber, which is the space of the housing 210.

The target 242 is disposed between the plasma electrode 241 and the substrate W. The target 242 is fixed to a lower surface of the plasma electrode 241. The target 242 includes a source of a thin film which is deposited on the substrate W on the chuck plate 300. For example, the target 242 includes a chalcogenide compound, such as at least one of germanium (Ge), antimony (Sb), or tellurium (Te). When plasma is induced between the target 242 and the substrate W, source particles are generated from the target 242. The source particles are deposited on the substrate W to form a thin film. The number of source particles or the thickness of the thin film increases in proportion to the strength of the high frequency power or the plasma.

As described above, due to an asymmetric shape of the housing 210 and the insulation difference between the housing 210 and the substrate entrance 211, heat radiation is asymmetrically lost from a symmetric the chuck plate 300, causing an asymmetric temperature gradient of the chuck plate 300. The substrate processing apparatus 1A according to an embodiment, as described above in association with FIG. 2A, corrects an asymmetric temperature gradient of the chuck plate 300, based on an asymmetric radiation shield 100. Therefore, by using the radiation shield 100 and the substrate processing apparatus 1A that includes the same according to an embodiment, the temperature gradient of the chuck plate 300 becomes more uniform. In addition, because the temperature gradient of the chuck plate 300 becomes more uniform, the quality of the substrate W, on which a substrate processing process has been performed, is enhanced. For example, the substrate processing apparatus 1A according to an embodiment may enhance the productivity and quality of the substrate W.

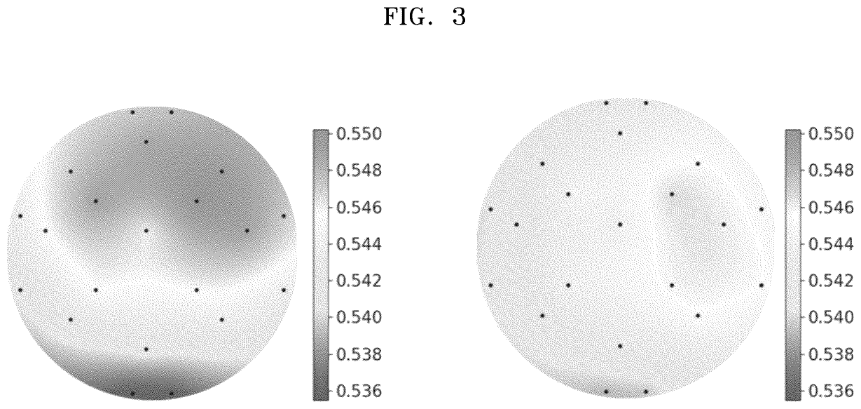

FIG. 3 illustrates extinction coefficient values of a substrate when no radiation shield is provided, and when a radiation shield according to an embodiment is provided.

Referring to FIG. 3, in an embodiment, when a thin film is formed on the substrate W through deposition, various variables can affect characteristics of the thin film. The variables, as described above, can affect characteristics of the thin film or the temperature uniformity of the chuck plate 300 that heats the substrate W. For example, the thickness of the thin film formed on the substrate W can change due to the non-uniform temperature of the chuck plate 300, or an extinction coefficient k of the physical properties of the thin film formed on the substrate W can change due to the non-uniform temperature of the chuck plate 300. An extinction coefficient is an optical constant and denote the degree of transmittance of light that passes through a thin film. Therefore, the physical properties of a thin film as well as the thickness of the thin film can be evaluated based on an extinction coefficient. For example, the roughness of a surface layer and the density difference caused by an empty space in a thin film can affect an extinction coefficient, and thus, characteristics of a thin film formed on the substrate W can be observed based on the extinction coefficient.

The left drawing of FIG. 3 illustrates an extinction coefficient value of a substrate in a substrate processing apparatus where no radiation shield 100 according to an embodiment is provided, and the right drawing of FIG. 3 illustrates an extinction coefficient value of the substrate W in the substrate processing apparatus 1 that includes the radiation shield 100 according to an embodiment.

As seen in the drawing a gradient of an extinction coefficient value of a thin film formed on the substrate W is enhanced. For example, an average value of an extinction coefficient of the left drawing of FIG. 3 is calculated to be 0.5450, and a standard deviation thereof is calculated to be 0.0147. An average value of an extinction coefficient of the right drawing of FIG. 3 is calculated to be 0.5431, and a standard deviation thereof is calculated to be 0.0073. Based on a result of a comparison of the left drawing and the right drawing of FIG. 3, the uniformity of physical properties of the thin film on the substrate W formed through the substrate processing apparatus 1 that includes the radiation shield 100 is enhanced.

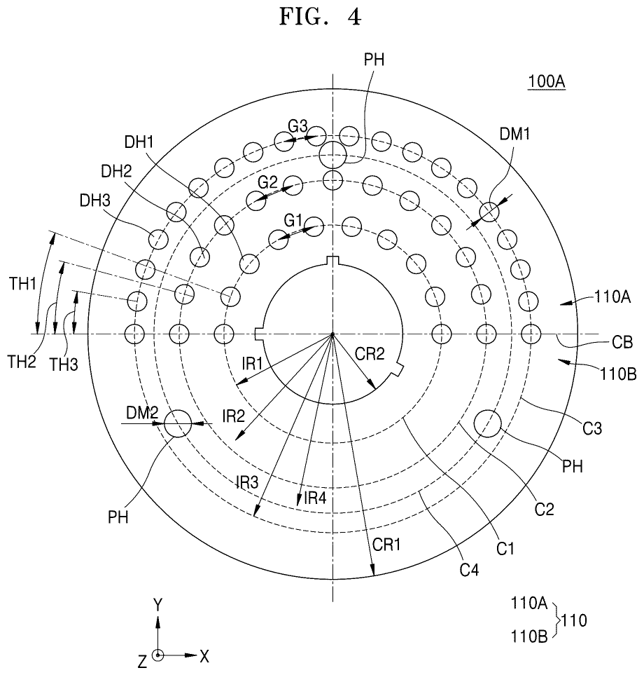

FIG. 4 is a plan view of a radiation shield 100A according to an embodiment. Repeated descriptions of components described above with reference to FIGS. 1 to 2B may summarized or omitted.

Referring to FIG. 4, the radiation shield 100A according to an embodiment includes a shield plate 110 and a plurality of through holes DH1 to DH3 that pass through the shield plate 110 and are asymmetrically arranged in the shield plate 110. A plurality of through holes DH1 to DH3 are formed in a first portion 110A of the shield plate 110, and no through holes DH1 to DH3 are formed in a second portion 110B of the shield plate 110. The radiation shield 100A, like the radiation shield 100 of FIG. 1 described above, is provided in the substrate processing apparatus 1 or 1A.

The plurality of through holes DH1 to DH3 are formed in the first portion 110A that is divided by the center line CB, which is a boundary. In addition, the plurality of through holes DH1 to DH3 are formed in the center line CB. A first virtual circle C1, a second virtual circle C2, a third virtual circle C3, and a fourth virtual circle C4, which are concentric circles in the shield plate 110, are defined. Values of each the first radius IR1, the second radius IR2, the fourth radius IR4, and the third radius IR3 increase in the order of the first radius IR1, the second radius IR2, the fourth radius IR4, and the third radius IR3.

In an embodiment of FIG. 4, a difference between the first radius IR1 and the second radius IR2 is the same as a difference between the second radius IR2 and the third radius IR3. This allows a plurality of through holes to be disposed in the shield plate 110 at a relatively uniform density, so that heat radiation can uniformly pass through the chuck plate 300.

Hereinabove, embodiments have been described in the specification with reference to the drawings. Therefore, it may be understood by those of ordinary skill in the art that various modifications and other equivalent embodiments may be implemented from the inventive concept. Accordingly, the spirit and scope of embodiments of the inventive concept may be defined based on the spirit and scope of the following claims.

What is claimed is:

1. A radiation shield, comprising
a shield plate that includes a first portion, a second portion, and a plurality of pin holes that pass through the shield plate, wherein
the first portion comprises a plurality of through holes that pass through the shield plate, and
the second portion does not include the plurality of through holes.

2. The radiation shield of claim 1, wherein
a planar shape of the shield plate is circular,
the first portion and the second portion are divided by a center line that passes through a center of the planar shaped shield plate, and
the shield plate further comprises a plurality of through holes formed along the center line and that pass through the shield plate.

3. The radiation shield of claim 2, wherein
a first virtual circle, a second virtual circle, and a third virtual circle, which are concentric circles in the shield plate, are defined on the shield plate,
the plurality of through holes comprise first through holes formed along the first virtual circle, second through holes formed along the second virtual circle, and third through holes formed along the third virtual circle, and
a radius from the center of the shield plate of each of the first virtual circle, the second virtual circle, and the third virtual circle increases in the order of the first virtual circle, the second virtual circle, and the third virtual circle.

4. The radiation shield of claim 3, wherein a number of through holes increases in an order of the first through holes, the second through holes, and the third through holes.

5. The radiation shield of claim 4, wherein
a difference between a second radius and a third radius is greater than a difference between a first radius and the second radius,
the first radius is a radius of the first virtual circle from the center,
the second radius is a radius of the second virtual circle from the center, and
the third radius is a radius of the third virtual circle from the center.

6. The radiation shield of claim 4, wherein
a difference between a first radius and a second radius is equal to a difference between the second radius and a third radius,
the first radius is a radius of the first virtual circle from the center,
the second radius is a radius of the second virtual circle from the center, and
the third radius is a radius of the third virtual circle from the center.

7. The radiation shield of claim 5, wherein
separation distances between the first through holes are equal to each other,
separation distances between the second through holes are equal to each other, and
separation distances between the third through holes are equal to each other.

8. The radiation shield of claim 1, wherein, with respect to a plane, a ratio of an area of the first portion to an area of the second portion is between about 0.7 and about 0.9.

9. The radiation shield of claim 1, wherein
a second diameter is greater than a first diameter, and
the first diameter is a diameter of each of the plurality of through holes, and the second diameter is a diameter of each of the plurality of pin holes.

10. The radiation shield of claim 3, wherein
the plurality of pin holes are uniformly formed along a fourth virtual circle,
the fourth virtual circle is defined in the shield plate and is concentric with the second virtual circle and the third virtual circle, and
a radius of the fourth virtual circle from the center is greater than a radius of the second virtual circle from the center and is less than a radius of the third virtual circle from the center.

11. The radiation shield of claim 9, wherein
the first diameter is between about 10 mm and about 16 mm,
the second diameter is between about 15 mm and about 21 mm,
a separation distance between the plurality of through holes is between about 16 mm and about 24 mm, and
a thickness of the shield plate is between about 2 mm and about 4 mm.

12. A substrate processing apparatus, comprising:
a housing that provides a chamber;
a chuck plate disposed in the chamber;
a shaft disposed at a lower end of the chuck plate and that supports the chuck plate;
a radiation shield disposed under and spaced apart from the chuck plate, wherein the shaft passes through the radiation shield; and
a substrate entrance formed in one surface of the housing that is located a first direction from the chuck plate,
wherein the radiation shield comprises a shield plate that includes a first portion, a second portion, and a plurality of pin holes that pass through the shield plate,
wherein the first portion comprises a plurality of through holes that pass through the shield plate and the second portion does not include the plurality of through holes.

13. The substrate processing apparatus of claim 12, wherein the second portion is closer to the substrate entrance than the first portion.

14. The substrate processing apparatus of claim 13, wherein the shield plate has a circular planar shape, and
the first portion and the second portion are divided by a center line that passes through a center of the shield plate, and the center line and the first direction are perpendicular to each other.

15. The substrate processing apparatus of claim 13, further comprising a plurality of through holes formed along the center line of the shield plate and that pass through the shield plate.

16. The substrate processing apparatus of claim 14, wherein
a first virtual circle, a second virtual circle, and a third virtual circle, which are concentric circles of the shield plate, are defined on the shield plate,
the plurality of through holes comprise first through holes formed along the first virtual circle, second through holes formed along the second virtual circle, and third through holes formed along the third virtual circle, and
a radius from the center of the shield plate of each of the first virtual circle, the second virtual circle, and the third virtual circle increases in the order of the first virtual circle, the second virtual circle, and the third virtual circle.

17. The substrate processing apparatus of claim 16, wherein a number of through holes increases in an order of the first through holes, the second through holes, and the third through holes.

18. The substrate processing apparatus of claim 16, wherein
a difference between a second radius and a third radius is greater than a difference between a first radius and the second radius,
the first radius is a radius of the first virtual circle from the center,
the second radius is a radius of the second virtual circle from the center,
the third radius is a radius of the third virtual circle from the center,
separation distances between the first through holes are equal to each other,
separation distances between the second through holes are equal to each other,
separation distances between the third through holes are equal to each other, and
with respect to a plane, a ratio of an area of the first portion to an area of the second portion is between about 0.7 to about 0.9.

19. The substrate processing apparatus of claim 18, wherein
a second diameter is greater than a first diameter,
the first diameter is a diameter of each of the plurality of through holes,
the second diameter is a diameter of each of the plurality of pin holes,
the plurality of pin holes are uniformly formed along a fourth virtual circle, and
the fourth virtual circle is defined in the shield plate and is concentric with the second virtual circle and the third virtual circle, and
a radius of the fourth virtual circle from the center is greater than a radius the second virtual circle from the center of and is less than a radius of the third virtual circle from the center.

20. A radiation shield, comprising:
a shield plate that includes a first portion, a second portion, and a plurality of pin holes that pass through the shield plate, wherein:
the shield plate has a planar circular shape,
the first portion and the second portion are divided by a center line that passes through a center of the shield plate,
the shield plate comprises a plurality of through holes that pass through the shield plate,
the plurality of through holes are disposed in the first portion and along the center line of the shield plate,
the second portion does not include the plurality of through holes,
a first virtual circle, a second virtual circle, a third virtual circle, and a fourth virtual circle, which are concentric circles of the shield plate, are defined on the shield plate,
a first radius is a radius of the first virtual circle from the center,
a second radius is a radius of the second virtual circle from the center,
a third radius is a radius of the third virtual circle from the center,
a fourth radius is a radius of the fourth virtual circle from the center,
lengths of the first to fourth radii increase in an order of the first radius, the second radius, the fourth radius, and the third radius and a difference between the second radius and the third radius is greater than a difference between the first radius and the second radius,
the plurality of through holes comprise first through holes formed along the first virtual circle, second through holes formed along the second virtual circle, and third through holes formed along the third virtual circle,
separation distances between the first through holes are equal to each other,
separation distances between the second through holes are equal to each other,
separation distances between the third through holes are equal to each other, and
a number of through holes increases in an order of the first through holes, the second through holes, and the third through holes,
the plurality of pin holes are uniformly formed along the fourth virtual circle,
a first diameter is a diameter of each of the plurality of through holes,
a second diameter is a diameter of each of the plurality of pin holes,
the second diameter is greater than the first diameter,
the first diameter is between about 10 mm and about 16 mm,
the second diameter is between about 15 mm and about 20 mm,
a separation distance between the plurality of through holes is between about 16 mm and about 24 mm, and
a thickness of the shield plate is between about 2 mm and about 4 mm.
